(19) United States
(12) Patent Application Publication
(10) Pub. No.: US 2026/0253658 A1
(43) Pub. Date: Aug. 27, 2026

(54) BUILT-IN SELF-TRIM FOR VOLTAGE REGULATORS

(71) Applicant: Taiwan Semiconductor Manufacturing Company, Ltd., Hsinchu (TW)

(72) Inventors: Perng-Fei Yuh, Hsinchu City (TW); Tomohiko Yano, Hsinchu City (TW)

(73) Assignee: Taiwan Semiconductor Manufacturing Company, Ltd., Hsinchu (TW)

(21) Appl. No.: 19/064,929

(22) Filed: Feb. 27, 2025

(51) Int. Cl. G11C 29/02; G05F 3/24; G11C 17/18

(52) U.S. Cl. CPC G11C 29/028; G05F 3/242; G11C 17/18; G11C 29/021

(57) ABSTRACT

Systems, devices, and methods of operating said systems and devices are disclosed. In one aspect, a system includes a memory circuit, a plurality of bias generator circuits each corresponding to a respective input of the memory circuit, and a built-in self-trim circuit. The built-in self-trim circuit can receive a feedback signal from a first bias generator circuit of the plurality of bias generator circuits. The built-in self-trim circuit can generate a trim code for the first bias generator circuit based on the feedback signal and a voltage reference, causing the first bias generator circuit to generate an output voltage for the respective input of the memory array.

### BACKGROUND

An integrated circuit (IC) can contain a variety of hardware circuit devices or types of logic, including FPGAs, application-specific integrated circuits (ASICs), logic gates, registers, or transistors, in addition to various interconnections between the circuit devices. The IC can be manufactured using or composed of semiconductor materials, for instance, as part of electronic devices, such as computers, portable devices, smartphones, internet of thing (IoT) devices, etc. Developments and increasing complexity of the ICs have prompted increased demands for higher computational efficiency and speed. More specifically, the ICs can be configurable and/or programmable to perform computations in sequences or variations desired by the manufacturer, developer, technician, or programmer, among others.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a block diagram of an example memory system implementing built-in self-trim circuits for voltage regulator circuits, in accordance with some embodiments of the present disclosure.

FIG. 2 illustrates a block diagram of an example built-in self-trim circuit used to calibrate a voltage regulator circuit, in accordance with some embodiments of the present disclosure.

FIG. 3 illustrates a block diagram of the example built-in self-trim circuit of FIG. 2 in an arrangement for calibrating multiple voltage regulator circuits, in accordance with some embodiments of the present disclosure.

FIG. 4 illustrates a block diagram of another example built-in self-trim circuit used to calibrate a voltage regulator circuit based on a direct voltage output, in accordance with some embodiments of the present disclosure.

FIG. 5 illustrates a block diagram of the example built-in self-trim circuit of FIG. 4 in an arrangement for calibrating multiple voltage regulator circuits, in accordance with some embodiments of the present disclosure.

FIG. 6 illustrates a block diagram of another example memory system implementing built-in self-trim circuits for voltage regulator circuits using one-time programmable memory circuits, in accordance with some embodiments of the present disclosure.

FIG. 7 illustrates a block diagram of an example built-in self-trim circuit for calibrating multiple voltage regulator circuits using one-time programmable memory circuits, in accordance with some embodiments of the present disclosure.

FIG. 8 illustrates a diagram illustrating an example binary search process that may be implemented via one or more circuits described herein, in accordance with some embodiments of the present disclosure.

FIG. 9 illustrates a diagram illustrating an example linear search process that may be implemented via one or more circuits described herein, in accordance with some embodiments of the present disclosure.

FIG. 10 illustrates a flowchart of an example method to operate the disclosed circuits described herein, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Voltage regulators can be employed in memory devices to generate precise bias voltages for memory operations. However, achieving accurate voltage bias often necessitates the implementation of trimming within memory circuits, which introduces additional testing costs and requires extra chip area for on-chip trim-bit storage. Traditional approaches to mitigating trimming requirements, such as auto-zero or chopper stabilizer designs, can alleviate some of these issues but result in a number of drawbacks, including slower circuit operation, increased circuit area, or the introduction of clock noise.

Trimming voltage regulators involves generating “trim codes,” which are numerical representations of adjustments to voltage output that are determined to achieve a desired output voltage. Trimming numerous voltage regulators on a single chip using conventional approaches leads to extensive testing times, as correct trim codes must be determined for each voltage regulator in the memory chip. Additionally, a significant amount of on-chip eFuse storage is required to retain these trim codes. Conventional approaches involve using an external tester circuit to set the trim codes, which involves loading trim bits into registers on the chip, measuring the analog voltage with the tester, comparing the measured voltage against an accurate voltage reference, and adjusting the trim bits based on the comparison results. This iterative process, which includes waiting for the voltage to settle and repeating the measurement and comparison until the voltage is sufficiently close to the target reference, is inherently slow and contributes significantly to the overall die cost.

To address these and other challenges, the techniques described herein introduce a built-in self-trimming engine designed to reduce testing time and cost, as well as minimize the need for one-time programmable (OTP) storage for trim codes. The circuits described herein can incorporate self-calibrated comparator(s) or operational amplifier(s) that can perform trimming on-chip without the need for external calibration tools. In some implementations, a single trimming circuit can be utilized to set the trim codes for all regulators in a memory device. The trimming circuits described herein can automatically execute on device power-on or reset, enabling memory devices to be completely powered down after trimming is completed.

For example, the trimming circuits described herein are engineered to automatically calibrate all voltage regulators to the desired accuracy by adjusting their trim codes during the initial power-up sequence. To do so, the built-in self-trimming circuits described herein can automatically iterate through each memory device, using feedback from the voltage regulator to update and store trim codes in a trimming register of the voltage regulator. In some implementations, OTP circuits such as eFuses or other memory elements can be used to persistently store generated trim codes after calibration, which in some implementations may reduce overall device power-on time.

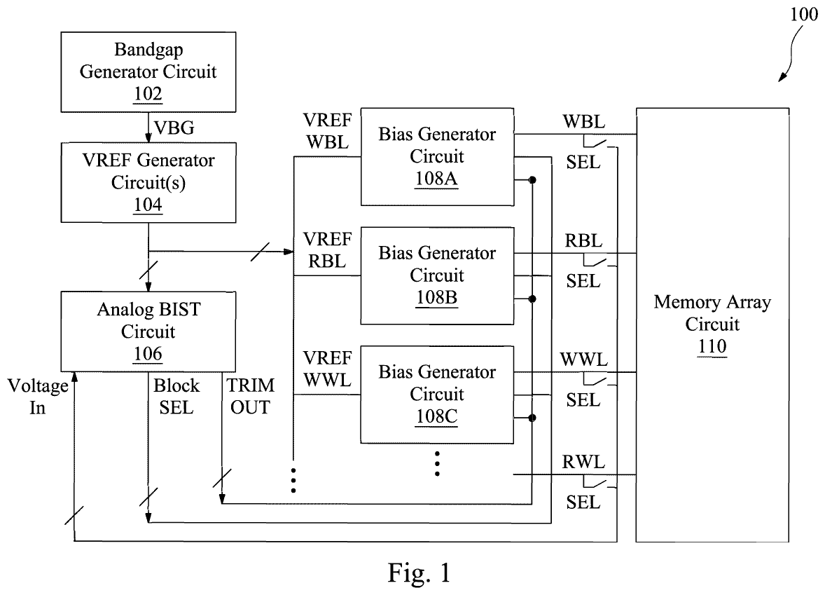

FIG. 1 illustrates a block diagram of an example memory system 100 implementing a built-in self-trimming (BIST) circuit 106, in accordance with some embodiments of the present disclosure. The memory system 100 is shown as including a bandgap voltage generator circuit 102, a voltage reference generator circuit 104, an analog BIST circuit 106, a set of bias generator circuits 108A-108C (sometimes generally referred to as “bias generator circuit(s) 108” or “voltage regulator circuit(s) 108”), and a memory array circuit 110. Each of the components of the memory system 100 may be part of a single memory device, for example, provided on a single semiconductor die or multiple semiconductor dies in communication with one another. The analog BIST circuit 106 can be a built-in component of the memory system rather than an external component.

The memory system 100 may include one or more logic gates and sub-circuits, each of which may be constructed from one or more logic gates. Logic gates are electronic devices that perform logical operations on one or more input signals to produce a single output signal. Various embodiments of the circuits and logic gates that implement the memory system 100 may include various transistors. The transistors described herein may have a certain type (n-type or p-type), but embodiments are not limited thereto. The transistors can be any suitable type of transistor including, but not limited to, metal oxide semiconductor field effect transistors (MOSFET), complementary metal oxide semiconductors (CMOS) transistors, P-channel metal-oxide semiconductors (PMOS), N-channel metal-oxide semiconductors (NMOS), bipolar junction transistors (BJT), high voltage transistors, high frequency transistors, P-channel and/or N-channel field effect transistors (PFETs/NFETs), FinFETs, planar MOS transistors with raised source/drains, nanosheet FETs, nanowire FETs, or the like.

The memory system 100 is shown as including the bandgap voltage generator 102. The bandgap voltage generator 102 can provide a stable reference voltage, sometimes referred to as a bandgap voltage, which can be relatively insensitive to temperature variations. The bandgap voltage generator 102 can include any suitable circuit for generating a bandgap voltage. In some implementations, the bandgap voltage generator 102 can include a combination of a forward-biased diode-connected transistor and a resistor network, which together can generate a voltage that is proportional to the bandgap voltage of the semiconductor material of the bandgap voltage generator 102. In some implementations, the bandgap voltage generator 102 can incorporate a current mirror circuit to ensure that the generated voltage remains consistent across different operating conditions. The generated bandgap voltage can subsequently be provided to the voltage reference generator 104, to facilitate generation of a precise and stable reference voltage.

The memory system 100 is shown as including the bandgap voltage generator 102. The voltage reference generator 104 can receive the bandgap voltage from the bandgap voltage generator 102 and can generate one or more reference voltages that are provided to the analog BIST circuit 106 and the one or more bias generator circuits 108. The voltage reference generator 104 can include a variety of components such as operational amplifiers, resistive networks, and voltage divider circuits. In some implementations, the voltage reference generator 104 can utilize an operational amplifier or similar circuit that can amplify the bandgap voltage and generate one or more stable reference voltages. The operational amplifier can be coupled with a resistive network to scale the bandgap voltage to the desired reference voltage levels. In some implementations, the voltage reference generator 104 can incorporate voltage divider circuits to further refine the generated reference voltages to conform to the reference voltage inputs of the analog BIST circuit 106 and the bias generator circuits 108. In some implementations, the voltage reference generator 104 can include temperature compensation circuits to maintain the stability of the reference voltages across varying operating temperatures.

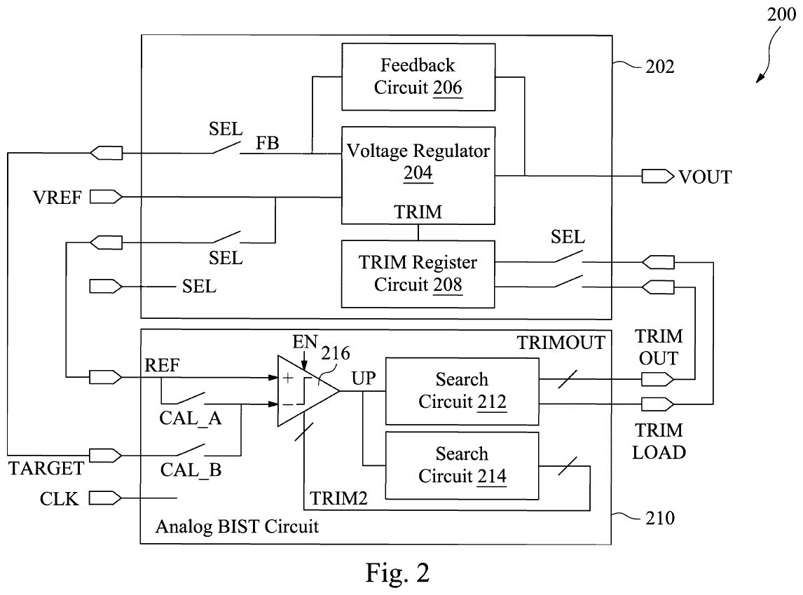

The memory system is shown as including the analog BIST circuit 106. As shown, the analog BIST circuit 106 can receive the reference voltage from the voltage reference generator 104 and can generate output trim codes (shown as “TRIM OUT”) for one or more bias generator circuits 108. In some implementations, the analog BIST circuit 106 can include a control circuit that outputs a block selection signal (shown as “block SEL”) to select one or more of the bias generator circuits 108 for trimming. Further details relating to the structure of the analog BIST circuit 106 are described in connection with FIG. 2.

The analog BIST circuit 106 can facilitate the automatic generation of trim codes for one or more of the bias generator circuits 108, such that the generated bias voltages meet generate output voltages compatible with the memory array circuit 110. As shown, the analog BIST circuit 106 can receive one or more feedback voltages (shown here as “Voltage in”) from the selected bias generator circuits 108, which can be used in connection with the trimming operations described in further detail herein. The analog BIST circuit 106 can use the received feedback voltage to iteratively generate trim codes for the selected bias generator circuits 108. The iterative process can involve adjusting the trim codes until the feedback voltages match the reference voltage within a specified tolerance.

In some implementations, the analog BIST circuit 106 can automatically execute the trimming process upon device power-on or reset (e.g., by receiving a corresponding reset signal, power-on signal, or initialization signal). To do so, the control circuit within the analog BIST circuit 106 can sequentially select each of the bias generator circuits 108 for trimming, using the block selection signal to isolate and adjust individual bias generator circuits 108. The analog BIST circuit 106 can generate and store the trim codes for each selected bias generator circuit 108 within a corresponding trim register for those bias generator circuits 108.

The memory system 100 is shown as including one or more bias generator circuits 108. Each bias generator circuits 108 can generate a corresponding bias voltage for a corresponding input signal of the memory array circuit 110, as shown. To do so, each bias generator circuit 108 can receive a corresponding reference voltage from the voltage reference generator 104, which may correspond to a respective input of the memory array circuit 110. For example, the bias generator circuit 108A can receive a reference voltage corresponding to an input voltage for a write bit line of the memory array circuit 110. The bias generator circuit 108 can generate a bias voltage for one or more voltage signals for the memory array circuit, including but not limited to write bit line voltages, read bit line voltages, write word line voltages, or read word line voltages, among others. Further details relating to the structure and functionality of each bias generator circuit 108 are described in connection with FIG. 2.

Each bias generator circuit 108 can include one or more registers that store trim codes generated by the analog BIST circuit 106, as described in further detail herein. The trim codes can be used to adjust the generated bias voltages such that they conform to the requirements of the memory array circuit 110. In one example, the bias generator circuit 108 can include a voltage regulator circuit including an operational amplifier or similar component that receives the trim codes to modify the output bias voltages. As shown, each of the bias generator circuits 108 can provide voltage feedback to the analog BIST circuit 106 to facilitate the trimming operation. In some implementations, the block select signal can be used to select which of the bias generator circuits 108 is to be trimmed.

The memory system 100 is shown as including at least one memory array circuit 110 that can receive bias voltage signals from one or more or more bias generator circuits 108. The memory array circuit 110 can include an array of any number of memory elements, including but not limited to dynamic random-access memory (DRAM) memory cells, static random-access memory (SRAM) cells, flash memory cells, eFuse memory cells, or any other type of memory cell capable of storing information electronically. The memory array circuit 110 can perform read and write operations to store and retrieve data. In some implementations, the memory array circuit 110 can include additional components such as sense amplifiers, decoders, and input/output circuits to support various memory operations.

FIG. 2 illustrates a block diagram of an example built-in self-trim circuit 200 used to calibrate a voltage regulator circuit, in accordance with some embodiments of the present disclosure. The built-in self-trim circuit 200 is shown as including a bias generator circuit 202 and the analog BIST circuit 210. The bias generator circuit 202 can be similar to and include any of the structure and implement any of the functionality of, the bias generator circuit 108 of FIG. 1. The analog BIST circuit 210 can be similar to and include any of the structure and implement any of the functionality of, the analog BIST circuit 106 of FIG. 1.

The built-in self-trim circuit 200 may include one or more logic gates and sub-circuits, each of which may be constructed from one or more logic gates. Logic gates are electronic devices that perform logical operations on one or more input signals to produce a single output signal. Various embodiments of the circuits and logic gates that implement the built-in self-trim circuit 200 may include various transistors. The transistors described herein may have a certain type (n-type or p-type), but embodiments are not limited thereto. The transistors can be any suitable type of transistor including, but not limited to, MOSFET, CMOS transistors, PMOS, NMOS, BJT, high voltage transistors, high frequency transistors, PFETs/NFETs, FinFETs, planar MOS transistors with raised source/drains, nanosheet FETs, nanowire FETs, or the like.

The bias generator circuit 202 is shown as including a voltage regulator circuit 204, a feedback circuit 206, and a trim register circuit 208. The bias generator circuit 202 can receive a selection input (shown here as “SEL”) that is activated (e.g., in a logic high state, in an active logic state, etc.) when the bias generator circuit 202 is selected for the trimming operations described herein. As shown, the bias generator circuit 202 can include switches at the input of the trim register circuit that are closed when the selection input is active, enabling modification of the trim code stored in the trim register circuit 208. The bias generator circuit 202 includes another switch at the output of the feedback circuit 206, which is closed when the selection input is in the active state, enabling the bias generator circuit 202 to output the feedback from the feedback circuit 206 to the analog BIST circuit 210, as shown. The bias generator circuit 202 includes a fourth switch coupled to the voltage reference input (shown as “VREF”), which when closed (e.g., when the selection input is active), provides the voltage reference as output to the analog BIST circuit 210, as shown.

The voltage regulator circuit 204 can be any type of voltage generation circuit, including but not limited to a low-drop-out (LDO) voltage down converter, charge pumps, or other voltage generators. The voltage regulator circuit 204 can generate the output voltage signal (shown as “VOUT”), which can be used as a bias voltage for a memory circuit, such as the memory array circuit 110 of FIG. 1. The voltage regulator circuit 204 can receive the voltage reference input and the feedback signal (shown as “FB”) generated by the feedback circuit 206. The voltage regulator circuit 204 can receive trim codes from the trim register circuit 208, which can be used to fine-tune the output voltage signal as described in further detail herein.

The voltage regulator circuit 204 can generate the output voltage such that the feedback signal, which is generated by the feedback circuit 206 based on the output voltage, is equal to the reference voltage when affected by the trim codes. The trim codes received by the voltage regulator circuit 204 can adjust the internal parameters of the voltage regulator circuit 204, causing the output voltage of the voltage regulator circuit 204 to be modified. For example, the trim codes can modify the input offset voltage of an operational amplifier within the voltage regulator circuit 204, the gain of an operational amplifier within the voltage regulator circuit 204, or any other parameter of any component of the voltage regulator circuit 204. In some implementations, the trim codes can adjust the resistance values of resistive elements within the voltage regulator circuit 204, which can influence the voltage division and, consequently, the output voltage.

The feedback circuit 206 can receive the voltage output (VOUT) of the voltage regulator circuit 204 and generate the feedback signal (FB). The feedback circuit 206 may include a voltage divider or another type of circuit to deterministically reduce the output voltage. For example, the feedback circuit 206 can include a resistive voltage divider network, which can proportionally reduce the output voltage to a level suitable for comparison with the reference voltage. The feedback circuit 206 can have circuit elements (e.g., resistor dividers, etc.) selected such that, when the desired output voltage is generated, the generated feedback signal is equal to the reference voltage. In some implementations, the feedback circuit 206 can include additional components, such as operational amplifiers or comparators, to further refine the feedback signal and ensure that it matches the reference voltage under various operating conditions.

The trim register circuit 208 can include one or more storage elements, such as flip-flops, latches, or other storage elements, to store trim codes for the voltage regulator circuit 204. The trim register circuit 208 can receive a trim load signal (shown as “TRIM LOAD”) from the analog BIST circuit 210, indicating that a trim code is to be written to the trim register circuit 208. The trim register circuit 208 can receive the trim code (shown as “TRIM OUT”) from the analog BIST circuit 210 and store it in the flip-flops, latches, or other memory elements. The trim register circuit 208 can provide the stored trim code to the voltage regulator circuit 204 to adjust the output voltage.

The analog BIST circuit 210 is shown as including a first searching circuit 212, a second searching circuit 214, and a comparison circuit 216. Although shown here as a comparator, it should be understood that the comparison circuit 216 can include any type of circuit that can compare two inputs, including but not limited to an operational amplifier. The analog BIST circuit 210 can receive a clock signal (shown as “CLK”), which can synchronize the various logical components of the analog BIST circuit 210. The analog BIST circuit 210 can receive the feedback signal and the voltage reference signal from the bias generator circuit 202 as the target input (shown as “TARGET”) and the reference input (shown as “REF”), respectively. The analog BIST circuit 210 can generate trim codes via the TRIM OUT and TRIM LOAD signals using the techniques described herein.

Prior to generating trim codes, the analog BIST circuit 210 can perform a self-calibration process, to calibrate the output of the comparison circuit 216. As shown, the analog BIST circuit 210 includes two switches at the second input of the comparison circuit 216. The first switch can be closed during the self-calibration process and can be controlled by a first calibration signal (shown as “CAL_A”). When the first switch is in the closed state closed, the second switch is in the open state, and the first switch causes both inputs of the comparison circuit 216 to be set to the reference voltage. The second switch can be closed during the trimming process for the bias generator circuit 202 and can be controlled by a second calibration signal (shown as “CAL_B”). When the second switch is in the closed state closed, the first switch is in the open state (following calibration), and the second switch causes the second input of the comparison circuit 216 to be set to the feedback voltage.

The first and second calibration circuits can be provided, for example, from a control circuit, which may be included as part of or in communication with the analog BIST circuit 210. In some implementations, the comparison circuit 216 can include an enable input, which can receive an enable signal that enables the comparison circuit 216 to generate an output. The comparison circuit 216 can operate as an error amplifier to amplify the small voltage difference between its first and second inputs into an output error signal (shown here as “UP”), to be used in self-calibration and/or generating trim codes according to the techniques described herein.

To perform calibration, the first calibration signal can be set to an active logic state and the second calibration signal can be set to an inactive logic state, causing both inputs of the comparison circuit 216 to receive the voltage reference signal (e.g., an equal voltage signal). During the self-calibration process, the output of the comparison circuit 216 can indicate an internal error of the comparison circuit 216, which is to be compensated by second trim codes (shown here as “TRIM2”) generated using the second search circuit 214.

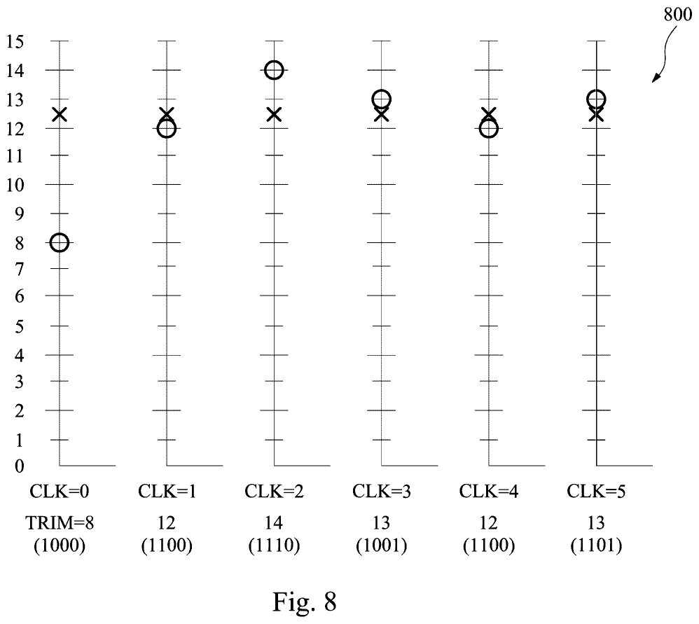

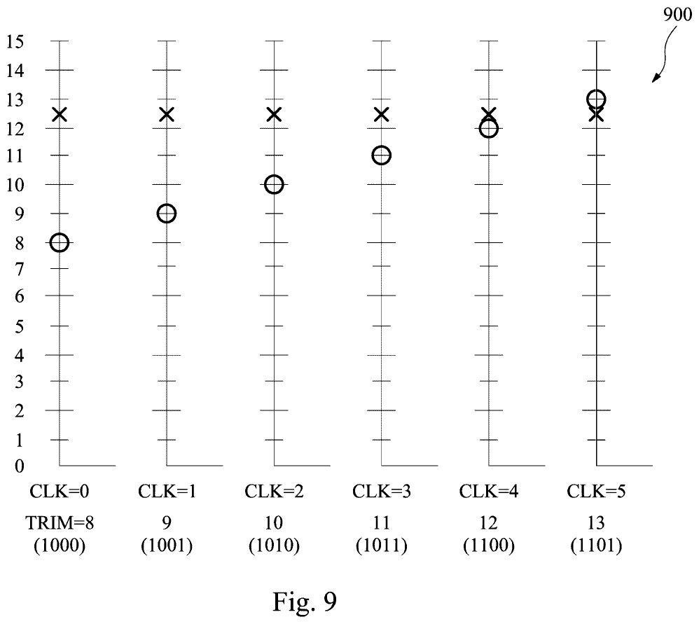

The first search circuit 212 and the second search circuit 214 can each be circuits that implement a searching operation to generate trim codes. In some implementations, the first search circuit 212 and the second search circuit 214 can be decision tree circuits that implement a binary search operation. Further details of the binary search operation are described in connection with FIG. 8. In some implementations, the first search circuit 212 and the second search circuit 214 each can be counter circuits that implement a linear search operation. Further details of the linear search operation are described in connection with FIG. 9.

To perform self-calibration, the second search circuit 214 can iteratively apply a search algorithm (e.g., binary search, linear search) to converge to a trim code for the comparison circuit 216. At the start of the self-calibration process, the second search circuit 214 can be initialized to include an initial set of trim codes (e.g., stored in an internal register and provided as output), which can be iteratively adjusted each clock cycle (or set of clock cycles) based on the output of the comparison circuit 216. If the comparison circuit 216 outputs a logic high, the second search circuit 214 can adjust the trim codes to reduce the detected voltage difference. Conversely, if the comparison circuit 216 outputs a logic low, the second search circuit 214 can adjust the trim codes to increase the detected voltage difference. The second search circuit 214 can update the second trim values (e.g., trim codes) until the comparison circuit 216 alternates between logic high and logic low outputs, indicating that the detected voltage difference of the inputs as detected by the comparison circuit 216 is minimized. Once this condition is detected, the second search circuit 214 and/or a control circuit can generate a signal that indicates the comparison circuit 216 is calibrated.

Once self-calibration of the comparison circuit 216 has been performed, trim codes for the voltage regulator circuit 204 can be generated using the first search circuit 212. To do so, the first calibration signal can be set to an inactive logic state and the second calibration signal can be set to an active logic state, causing the first input of the comparison circuit 216 to receive the voltage reference signal and the second input of the comparison circuit 216 to receive the feedback signal (e.g., via the TARGET input port of the analog BIST circuit 210). During the calibration process for the voltage regulator circuit 204, the output of the comparison circuit 216 can indicate an internal error of the comparison circuit 216, which is to be compensated by the trim codes generated using the second search circuit 214 as the TRIM OUT signal.

To perform calibration of the voltage regulator circuit 204, the first search circuit 212 can iteratively apply a search algorithm (e.g., binary search, linear search) to converge to a trim code for the voltage regulator circuit 204. At the start of the calibration process, the first search circuit 212 can be initialized to store an initial trim code (e.g., stored in an internal register and provided as output), which can be iteratively adjusted each clock cycle (or set of clock cycles) based on the output of the comparison circuit 216. The first search circuit 212 can generate a trim code for the search operation each clock cycle (or set of clock cycles) and can automatically assert the trim load (shown as “TRIM LOAD”) signal to write the trim code to the storage elements of the trim register circuit 208.

The trim codes written to the trim register circuit 208 can cause the voltage regulator circuit 204 to change the output voltage, which causes a corresponding change in the feedback signal generated by the feedback circuit 206. The feedback signal is then provided to the comparison circuit 216 for a comparison during one or more subsequent clock cycles. If the comparison circuit 216 outputs a logic high, the first search circuit 212 can adjust the trim codes to reduce the detected voltage difference. Conversely, if the comparison circuit 216 outputs a logic low, the first search circuit 212 can adjust the trim codes to increase the detected voltage difference. The second search circuit 214 can iteratively update the trim codes provided to the bias generator circuit 202 until the comparison circuit 216 alternates between logic high and logic low outputs, indicating that the detected voltage difference of the inputs as detected by the comparison circuit 216 is minimized. Once this condition is detected, the first search circuit 212 and/or a control circuit can generate a signal that indicates the voltage regulator 204 is calibrated.

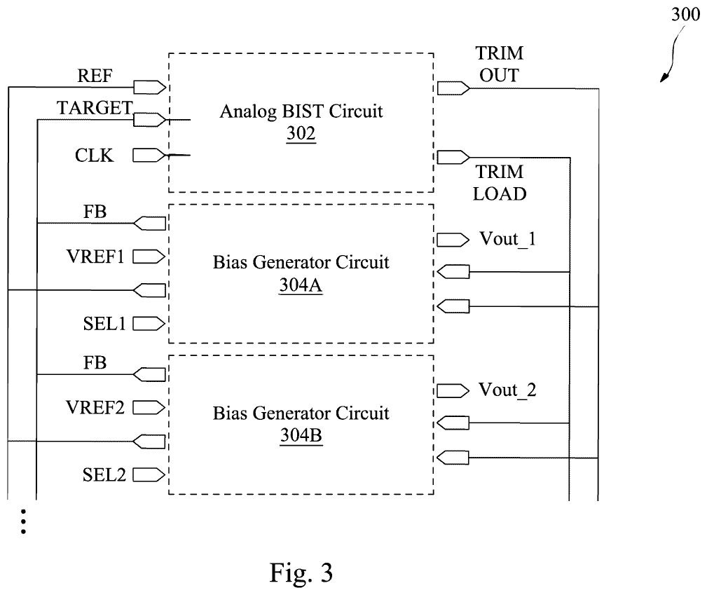

FIG. 3 illustrates a block diagram an example memory system 300, which includes an example built-in self-trim circuit of FIG. 2 in an arrangement for calibrating multiple voltage regulator circuits, in accordance with some embodiments of the present disclosure. The memory system 300 is shown as including the analog BIST circuit 302 and one or more bias generator circuits 304A-304B (sometimes generally referred to as the “bias generator circuit(s) 304”). The analog BIST circuit 302 can be similar to and include any of the structure and implement any of the functionality of, the analog BIST circuit 210 of FIG. 2. Each of the bias generator circuit 304 can be similar to and include any of the structure and implement any of the functionality of, the bias generator circuit 202 of FIG. 2. The analog BIST circuit 302 can perform iterative calibration of each of the bias generator circuits 304. In some implementations, prior to performing calibration of the bias generator circuits 304, the analog BIST circuit 302 can perform a self-calibration similar to the self-calibration process described in connection with FIG. 2.

The memory system 300 may include one or more logic gates and sub-circuits, each of which may be constructed from one or more logic gates. Logic gates are electronic devices that perform logical operations on one or more input signals to produce a single output signal. Various embodiments of the circuits and logic gates that implement the memory system 300 may include various transistors. The transistors described herein may have a certain type (n-type or p-type), but embodiments are not limited thereto. The transistors can be any suitable type of transistor including, but not limited to, MOSFET, CMOS transistors, PMOS, NMOS, BJT, high voltage transistors, high frequency transistors, PFETs/NFETs, FinFETs, planar MOS transistors with raised source/drains, nanosheet FETs, nanowire FETs, or the like.

Each of the bias generator circuits 304 can include a respective select signal (shown here as “SEL1” for the bias generator circuit 304A and “SEL2” for the bias generator circuit 304B). Although two bias generator circuits 304 are shown here, it should be understood that any number of bias generator circuits 304, each with corresponding select signals and voltage reference signals. Following calibration of the analog BIST circuit 302, one of the bias generator circuits 304 can be selected while the other bias generator circuits 304 are deselected. Selection of a bias generator circuit 304 can be performed, for example, by a control circuit or by the analog BIST circuit 302. Selection of a bias generator circuit 304 can cause the feedback signal and the voltage reference from that bias generator circuit 304 to be provided as the target input and the voltage reference for the calibration process, as described in connection with FIG. 2.

The analog BIST circuit 302 can perform calibration using the techniques described in connection with FIG. 2, where the feedback signal is compared to the voltage reference to generate appropriate trim codes for the selected bias generator circuit 304. Once the calibration process is complete for the selected bias generator circuit 304, the calibrated bias generator circuit 304 can be deselected, and the next uncalibrated bias generator circuit 304 can be selected for calibration. This iterative process can be repeated until all of the bias generator circuits 304 have been calibrated. During each iteration, the analog BIST circuit 302 can generate and store the appropriate trim codes for the selected bias generator circuit 304. The trim codes can be used to adjust the output voltage of each bias generator circuit 304 to ensure that the feedback signal matches the voltage reference within a specified tolerance.

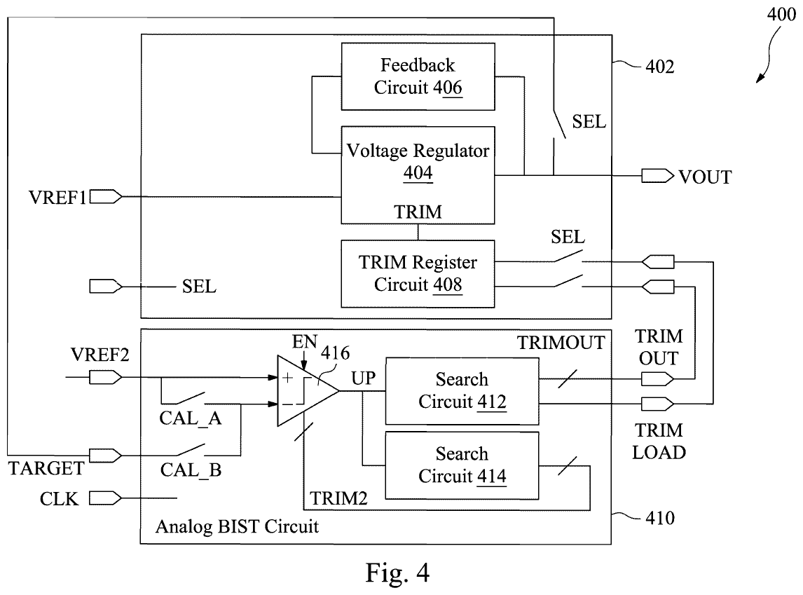

FIG. 4 illustrates a block diagram of an example built-in self-trim circuit 400 used to calibrate a voltage regulator circuit based on a direct voltage output, in accordance with some embodiments of the present disclosure. The built-in self-trim circuit 400 is shown as including a bias generator circuit 402 and the analog BIST circuit 410. The bias generator circuit 402 can be similar to and include any of the structure and implement any of the functionality of, the bias generator circuit 202 of FIG. 2. The analog BIST circuit 410 can be similar to and include any of the structure and implement any of the functionality of, the analog BIST circuit 210 of FIG. 2.

The built-in self-trim circuit 400 may include one or more logic gates and sub-circuits, each of which may be constructed from one or more logic gates. Logic gates are electronic devices that perform logical operations on one or more input signals to produce a single output signal. Various embodiments of the circuits and logic gates that implement the built-in self-trim circuit 400 may include various transistors. The transistors described herein may have a certain type (n-type or p-type), but embodiments are not limited thereto. The transistors can be any suitable type of transistor including, but not limited to, MOSFET, CMOS transistors, PMOS, NMOS, BJT, high voltage transistors, high frequency transistors, PFETs/NFETs, FinFETs, planar MOS transistors with raised source/drains, nanosheet FETs, nanowire FETs, or the like.

The bias generator circuit 402 is shown as including the voltage regulator circuit 404, the feedback circuit 406, and the trim register circuit 408, which may be similar to and include any of the structure and implement any of the functionality of the voltage regulator circuit 204, the feedback circuit 206, and the trim register circuit 208 of FIG. 2. The analog BIST circuit 410 is shown as including a comparison circuit 416, a first search circuit 412, and a second circuit 414, each of which may be similar to and include any of the structure and implement any of the functionality of the comparison circuit 216, the first search circuit 212, and the second circuit 214 of FIG. 2.

In the example built-in self-trim circuit 400, rather than providing the output of the feedback circuit 406 as a feedback signal (e.g., the target input signal) to the analog BIST circuit 410, the output voltage of the voltage regulator circuit 404 can be provided as the feedback/target input signal. To compensate for the voltage difference, two reference voltages can be used. A first voltage reference (shown as “VREF1”) can be provided as input to the bias generator circuit 402 to be compared to the feedback signal generated by the feedback circuit 406, similar to the voltage reference described in connection with FIG. 2. A second voltage reference (shown as “VREF2”) can be provided to the analog BIST circuit 410 to compare with the output voltage of the bias generator circuit 402. As shown, the output of the voltage regulator 402, in addition to being provided as the output voltage of the bias generator circuit 402, is coupled to a switch controlled by the select signal. If the select signal is active, the switch is closed, providing the output voltage to the analog BIST circuit 410 as the target input signal. The analog BIST circuit 410

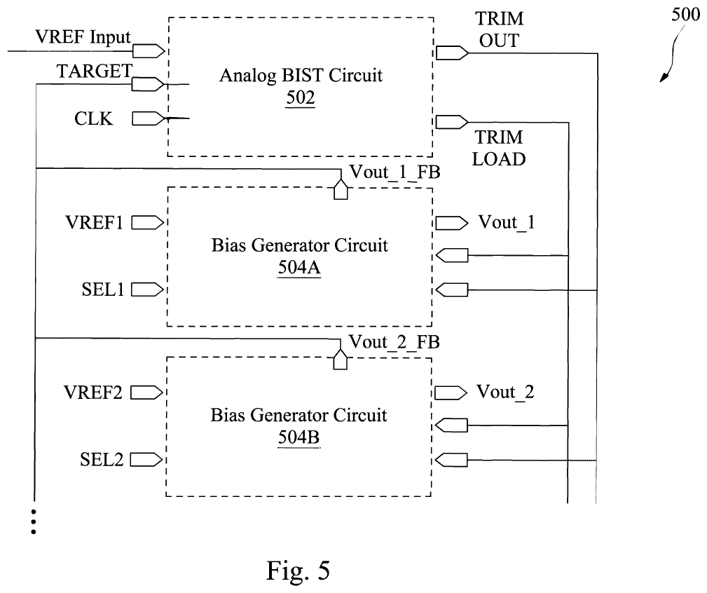

FIG. 5 illustrates a block diagram of an example memory system 500 including the built-in self-trim circuit of FIG. 4 in an arrangement for calibrating multiple voltage regulator circuits, in accordance with some embodiments of the present disclosure. The memory system 500 is shown as including the analog BIST circuit 502 and one or more bias generator circuits 504A-504B (sometimes generally referred to as the “bias generator circuit(s) 504”). The analog BIST circuit 502 can be similar to and include any of the structure and implement any of the functionality of, the analog BIST circuit 410 of FIG. 4. Each of the bias generator circuit 504 can be similar to and include any of the structure and implement any of the functionality of, the bias generator circuit 402 of FIG. 4. The analog BIST circuit 502 can perform iterative calibration of each of the bias generator circuits 504. In some implementations, prior to performing calibration of the bias generator circuits 504, the analog BIST circuit 502 can perform a self-calibration similar to the self-calibration process described in connection with FIG. 2.

The memory system 500 may include one or more logic gates and sub-circuits, each of which may be constructed from one or more logic gates. Logic gates are electronic devices that perform logical operations on one or more input signals to produce a single output signal. Various embodiments of the circuits and logic gates that implement the memory system 500 may include various transistors. The transistors described herein may have a certain type (n-type or p-type), but embodiments are not limited thereto. The transistors can be any suitable type of transistor including, but not limited to, MOSFET, CMOS transistors, PMOS, NMOS, BJT, high voltage transistors, high frequency transistors, PFETs/NFETs, FinFETs, planar MOS transistors with raised source/drains, nanosheet FETs, nanowire FETs, or the like.

The memory system 500 can be similar to the memory system 300 of FIG. 3, except including the analog BIST circuit and bias generator circuits described in connection with FIG. 4. Similar to the arrangement shown in FIGS. 3, 3ach of the bias generator circuits 504 can include a respective select signal (shown here as “SEL1” for the bias generator circuit 504A and “SEL2” for the bias generator circuit 504B). Although two bias generator circuits 504 are shown here, it should be understood that any number of bias generator circuits 504, each with corresponding select signals and voltage reference signals. Following calibration of the analog BIST circuit 502, one of the bias generator circuits 504 can be selected while the other bias generator circuits 504 are deselected. Selection of a bias generator circuit 504 can be performed, for example, by a control circuit or by the analog BIST circuit 502. Selection of a bias generator circuit 504 can cause the output voltage of the bias generator circuit 504 to be provided as the target input (shown here as “Vout_1_FB” for the bias generator circuit 504A and “Vout_2_FB” for the bias generator circuit 504B) for the analog BIST circuit 502, as described in connection with FIG. 4. Additionally, the control circuit can cause the voltage reference provided as input to the analog BIST circuit 502 to match the target voltage for which the selected bias generator circuit 504 is to be calibrated.

The analog BIST circuit 502 can perform calibration using the techniques described in connection with FIG. 2, where the voltage output of the selected bias generator circuit 504 is compared to the input voltage reference to generate appropriate trim codes for the selected bias generator circuit 504. Once the calibration process is complete for the selected bias generator circuit 504, the calibrated bias generator circuit 504 can be deselected, and the next uncalibrated bias generator circuit 504 can be selected for calibration. This iterative process can be repeated until all of the bias generator circuits 504 have been calibrated. During each iteration, the analog BIST circuit 502 can generate and store the appropriate trim codes for the selected bias generator circuit 504. The trim codes can be used to adjust the output voltage of each bias generator circuit 504 to ensure that the feedback signal matches the voltage reference within a specified tolerance, as described herein.

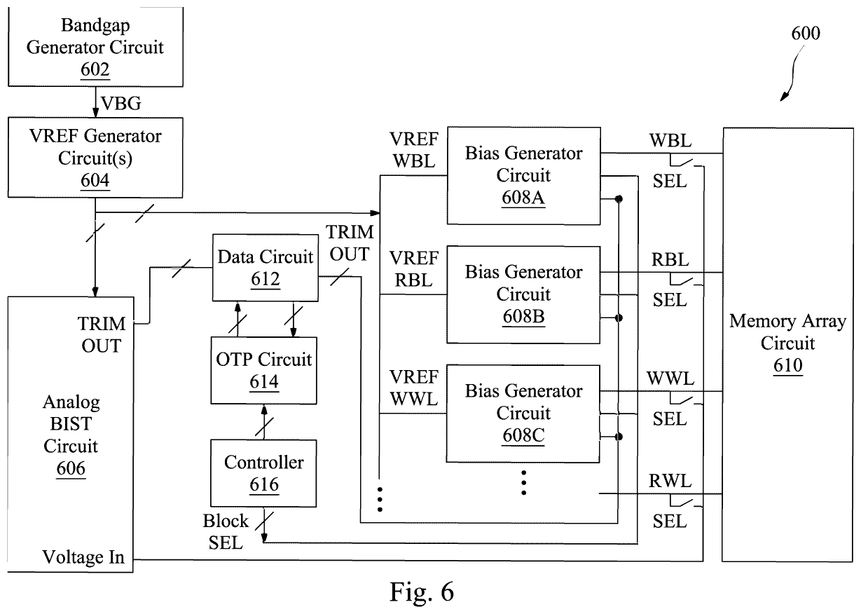

FIG. 6 illustrates a block diagram of another example memory system 600 implementing built-in self-trim circuits for voltage regulator circuits using one-time programmable memory circuits, in accordance with some embodiments of the present disclosure. The memory system 600 can be similar to the memory system 100 of FIG. 1. The memory system 600 is shown as including a bandgap voltage generator circuit 602, a voltage reference generator circuit 604, an analog BIST circuit 606, a set of bias generator circuits 608A-608C (sometimes generally referred to as “bias generator circuit(s) 608” or “voltage regulator circuit(s) 608”), a memory array circuit 610, a data circuit 612, an OTP circuit 614, and a controller 616.

The memory system 600 may include one or more logic gates and sub-circuits, each of which may be constructed from one or more logic gates. Logic gates are electronic devices that perform logical operations on one or more input signals to produce a single output signal. Various embodiments of the circuits and logic gates that implement the memory system 600 may include various transistors. The transistors described herein may have a certain type (n-type or p-type), but embodiments are not limited thereto. The transistors described herein may have a certain type (n-type or p-type), but embodiments are not limited thereto. The transistors can be any suitable type of transistor including, but not limited to, MOSFET, CMOS transistors, PMOS, NMOS, BJT, high voltage transistors, high frequency transistors, PFETs/NFETs, FinFETs, planar MOS transistors with raised source/drains, nanosheet FETs, nanowire FETs, or the like.

Each of the bandgap voltage generator circuit 602, the voltage reference generator circuit 604, the analog BIST circuit 606, the set of bias generator circuits 608, and the memory array circuit 610 can be similar to, and include any of the structure and implement any of the functionality of, the bandgap voltage generator circuit 102, the voltage reference generator circuit 104, the analog BIST circuit 106, the set of bias generator circuits 108, and the memory array circuit 110 of FIG. 1. In the arrangement shown in FIG. 6, the analog BIST circuit 606 can access the voltage output of the bias generator circuits in a manner similar to the arrangement described in connection with FIG. 4. However, it should be understood that in some implementations, the analog BIST circuit 606 can use a feedback signal from a feedback circuit as described in connection with FIG. 2.

The memory system 600 can operate in a similar manner to the memory system 100 of FIG. 1, additionally including persistent memory devices to store calculated trim codes for one or more of the bias generator circuits 608. Storing the trim codes in persistent memory allows the memory system 600 to initialize the bias generator circuits 608 with trim codes at boot/reset without requiring the bias generator circuits 608 to be recalibrated. Such approaches can reduce the amount of time to initialize the bias generator circuits 608 for use in connection with the memory array circuit 610, as the trim codes can be provided from persistent memory rather than being generated each time the memory system 600 is reset or reinitialized.

To implement these techniques, the analog BIST circuit 606 can perform an initial calibration of each of the bias generator circuits 608 to generate trim codes for storage in persistent memory elements. The calibration can be performed using similar approaches described herein. In this example, the controller 616 can control the block selection signal (e.g., the “block SEL” signal) to iteratively select each of the bias generator circuits 608. The analog BIST circuit 606 can perform the calibration techniques described herein to generate iteratively adjust trim codes (shown here as “TRIM OUT”) to the selected bias generator circuit 608. The trim codes can be provided from the analog BIST circuit 606 via the data circuit 612, which can also control read/write operations to the OTP circuit 614. In addition to providing the block selection signal, the controller 616 can provide an address signal corresponding to the selected bias generator circuit 608 as input to the OTP circuit 614.

Once an optimal trim code for the selected bias generator 608 is determined, the data circuit 612 can automatically perform a write operation (e.g., in response to a signal from the controller 616 and/or analog BIST circuit 606 indicating the calibration process is complete). The write operation can cause persistent memory elements of the OTP circuit 614 to be updated with the trim code determined for the selected bias generator circuit 608. The controller 616 can then select the next uncalibrated bias generator circuit 608, and the calibration process can be repeated until each of the bias generator circuits 608 has been calibrated and corresponding trim codes have been written to the OTP circuit 614.

The OTP circuit 614 can include any type of persistent memory element, including but not limited to OTP memory elements, eFuse memory elements, flash memory, or any other type of memory that can store trim codes for the bias generator circuits 608. The OTP circuit 614 can include control circuitry to facilitate read and write operations via the data circuit 612 and the controller 616. Once the OTP circuit 614 has been updated to include trim codes for each of the bias generator circuits 608, subsequent resets and/or initializations of the bias generator circuits 608 need not necessarily involve calibration.

For example, to initialize the bias generator circuits 608 with trim codes, the controller 616 can iteratively provide block selection signals to each of the bias generator circuits 608, along with a corresponding address signal to the OTP circuit 614. To initialize a selected bias generator circuit 608, the data circuit 612 can issue a read operation to retrieve the trim codes stored by the OTP circuit 614 and provide the retrieved trim codes to the selected bias generator circuit 608 to update the trim register circuit thereof. This can be repeated until all trim registers of the bias generator circuits 608 are updated to include the previously generated trim codes stored by the OTP circuit 614. In some implementations, the OTP circuit 614 may include memory elements that can be rewritten. In such implementations, the bias generator circuits 608 may be recalibrated in response to a corresponding signal (e.g., from an external circuit, etc.) to update the OTP circuit 614 with updated trim codes for the bias generator circuits 608.

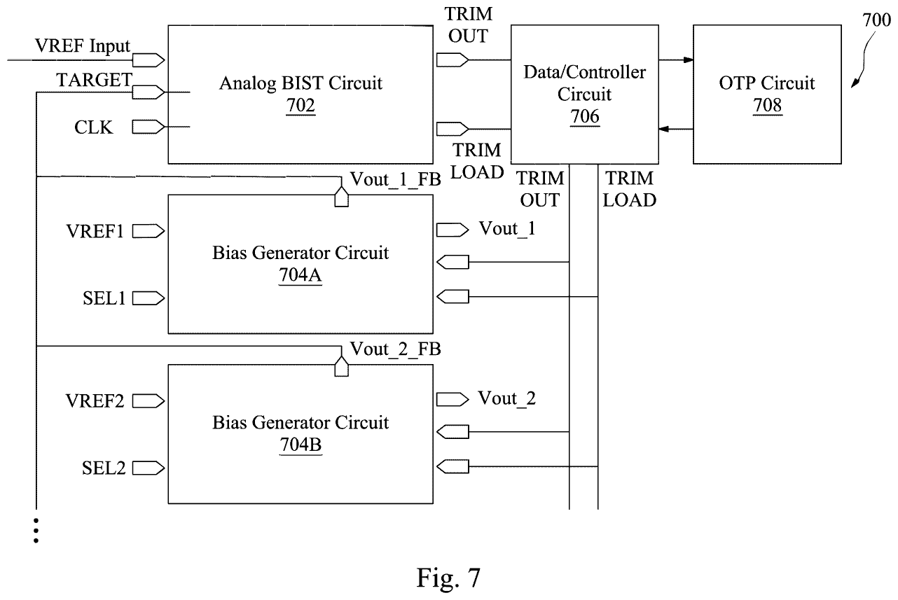

FIG. 7 illustrates a block diagram of an example memory system 700 for calibrating multiple voltage regulator circuits using one-time programmable memory circuits, in accordance with some embodiments of the present disclosure. The memory system 700 can be similar to the memory system 500 of FIG. 5. The memory system 700 is shown as including the analog BIST circuit 702 and one or more bias generator circuits 704A-374B (sometimes generally referred to as the “bias generator circuit(s) 704”). The analog BIST circuit 702 can be similar to and include any of the structure and implement any of the functionality of, the analog BIST circuit 510 of FIG. 5. Each of the bias generator circuit 704 can be similar to and include any of the structure and implement any of the functionality of, the bias generator circuits 504 of FIG. 5. The analog BIST circuit 702 can perform iterative calibration of each of the bias generator circuits 704. In some implementations, prior to performing calibration of the bias generator circuits 704, the analog BIST circuit 702 can perform a self-calibration similar to the self-calibration process described in connection with FIG. 2.

The memory system 700 may include one or more logic gates and sub-circuits, each of which may be constructed from one or more logic gates. Logic gates are electronic devices that perform logical operations on one or more input signals to produce a single output signal. Various embodiments of the circuits and logic gates that implement the memory system 700 may include various transistors. The transistors described herein may have a certain type (n-type or p-type), but embodiments are not limited thereto. The transistors can be any suitable type of transistor including, but not limited to, MOSFET, CMOS transistors, PMOS, NMOS, BJT, high voltage transistors, high frequency transistors, PFETs/NFETs, FinFETs, planar MOS transistors with raised source/drains, nanosheet FETs, nanowire FETs, or the like.

The memory system 700 is similar to the memory system 500, additionally including a data/controller circuit 706 and an OTP circuit 708. The data/controller circuit 706 can be similar to and include any of the structure and implement any of the functionality of, the controller circuit 616 and/or the data circuit 612 of the memory circuit 600 of FIG. 6. The OTP circuit 708 can be similar to and include any of the structure and implement any of the functionality of, the OTP circuit 614 of the memory system 600 of FIG. 6. As shown, rather than providing the output trim codes directly to a selected one of the bias generator circuits 704, the analog BIST circuit 702 can provide the trim codes (shown as “TRIM OUT”, with the corresponding “TRIM LOAD” signal to indicate a write) to the data/controller circuit 706.

As described in connection with FIG. 6, during a calibration phase for the bias generator circuits 704 (e.g., before trim codes are written to the OTP circuit 708), the data/controller circuit 706 can provide the trim codes to a selected bias generator circuit 704. Once the optimal trim code has been identified for the selected bias generator circuit 704, the data/controller circuit 706 can write the trim code to a corresponding memory element of the OTP circuit 708. This process can be repeated for each of the bias generator circuits 704. Rather than re-calibrating each of the bias generator circuits 704 on device reset or bootup, the data/controller circuit 706 can automatically retrieve the stored trim codes from the OTP circuit 708 and provide the trim codes to the corresponding bias generator circuits 704 (e.g., for storage in the trim register circuit, as described herein).

FIG. 8 illustrates a diagram illustrating an example binary search process 800 that may be implemented via one or more circuits described herein, in accordance with some embodiments of the present disclosure. The binary search process 800 can be implemented, for example, any of the search circuits described herein (e.g., the first or second search circuits 212 and 214, the first or second search circuits 412 and 414, etc.). For example, the binary search process 800 can be implemented using a decision tree circuit.

The diagram shown in FIG. 8 shows the binary search process 800 over five clock cycles, as indicated by the respective value of the CLK signal. Each clock cycle of the binary search process 800 is represented as a number line. The “X” provided on the number line indicates the “target” value for the search (the number to be determined via the binary search process 800). The search value (shown as “TRIM”) is illustrated in binary and decimal format beneath the number lines and represents the value of the search operation for the corresponding clock cycle. In this example, the trim code has a resolution of four bits, and therefore the search space (represented by the number line) can include up to sixteen values, ranging from zero to fifteen. However, it should be understood that any suitable resolution for the trim codes described herein may be used.

At the first iteration of the binary search process 800 (where the CLK has a value of zero), the trim code is initialized to the midpoint of the search space (indicated in binary as the having the most significant bit set to one and all other bits set to zero), which in this example is a value of eight. In FIG. 8, the search value of each clock cycle is represented on the number line as a circle. As described herein, the trim code of eight is provided to the trim register circuit (e.g., the trim register circuit 208) to adjust the output voltage of a voltage regulator (e.g., the voltage regulator 204).

At the next iteration (e.g., CLK=1), the output voltage (or feedback signal generated therefrom) is compared to a reference voltage. If the output voltage is less than the reference voltage, the most significant bit (e.g., the bit for the prior clock cycle) of the trim code can be maintained as a binary “1,” and the next most significant bit can be set to one. If the output voltage is less than the reference voltage, the most significant bit (e.g., the bit for the prior clock cycle) of the trim code can be set to a binary “0,” and the next most significant bit can be set to binary “1.” In this example, the output voltage is less than the reference voltage, and the trim code is set to twelve (binary “1100”).

At the next iteration (e.g., CLK=2), the output voltage (or feedback signal generated therefrom) is again compared to a reference voltage. If the output voltage is less than the reference voltage, the bit modified in the prior clock cycle (e.g., the second most significant bit) of the trim code can be maintained as a binary “1,” and the next most significant bit can be set to one. If the output voltage is greater than the reference voltage, the bit modified in the prior clock cycle (e.g., the second most significant bit) of the trim code can be set to a binary “0,” and the next most significant bit can be set to binary “1.” In this example, the output voltage is again less than the reference voltage, and the trim code is set to fourteen (binary “1110”).

At the next iteration (e.g., CLK=3), the output voltage (or feedback signal generated therefrom) is again compared to a reference voltage. If the output voltage is less than the reference voltage, the bit modified in the prior clock cycle (e.g., the third most significant bit) of the trim code can be maintained as a binary “1,” and the next most significant bit can be set to one. If the output voltage is greater than the reference voltage, the bit modified in the prior clock cycle (e.g., the third most significant bit) of the trim code can be set to a binary “0,” and the next most significant bit can be set to binary “1.” In this example, the output voltage is greater than the reference voltage (as indicated by the circle appearing above the “X”), and the trim code is set to thirteen (binary “1101”).

This process is repeated for the next iterations, until the least significant bit of the trim code toggles between iterations, as shown in clock cycles CLK=4 and CLK=5, which can indicate that the search has completed. As the binary search operation iteratively modifies each bit value in the trim code, the binary search process 800 for 2^{N} trim codes can be completed in N clock cycles. In this example, as sixteen trim codes are possible, the search is completed in four clock cycles (e.g., at CLK=4), where the trim code is set to 12 (binary “1100”).

FIG. 9 illustrates a diagram illustrating an example linear search process 900 that may be implemented via one or more circuits described herein, in accordance with some embodiments of the present disclosure. The linear search process 900 can be implemented, for example, any of the search circuits described herein (e.g., the first or second search circuits 212 and 214, the first or second search circuits 412 and 414, etc.). For example, the linear search process 900 can be implemented using a counter circuit.

The diagram shown in FIG. 9 shows the linear search process 900 over five clock cycles, as indicated by the respective value of the CLK signal. Each clock cycle of the linear search process 900 is represented as a number line. The “X” provided on the number line indicates the “target” value for the search (the number to be determined via the linear search process 900). The search value (shown as “TRIM”) is illustrated in binary and decimal format beneath the number lines and represents the value (e.g., trim code) resulting from the search operation for the corresponding clock cycle. In this example, the trim code has a resolution of four bits, and therefore the search space (represented by the number line) can include up to sixteen values, ranging from zero to fifteen. However, it should be understood that any suitable resolution for the trim codes described herein may be used.

At the first iteration of the linear search process 900 (where the CLK has a value of zero), the trim code is initialized to the midpoint of the search space (indicated in binary as the having the most significant bit set to one and all other bits set to zero), which in this example is a value of eight. In FIG. 9, the search value of each clock cycle is represented on the number line as a circle. As described herein, the trim code of eight is provided to the trim register circuit (e.g., the trim register circuit 208) to adjust the output voltage of a voltage regulator (e.g., the voltage regulator 204).

At the next iteration (e.g., CLK=1), the output voltage (or feedback signal generated therefrom) is compared to a reference voltage. If the output voltage is less than the reference voltage, the trim code is incremented by one. If the output voltage is greater than the reference voltage, the trim code is decremented by one. In this example, the output voltage is less than the reference voltage, and the trim code is set to nine (binary “1001”). This process repeats for multiple iterations until the direction of the search changes. This indicates that the linear search process 900 has been completed. In this example, the linear search operation continues for the five clock cycles, incrementing the trim code to thirteen (binary “1101”), after which the direction of the search changes direction (e.g., the output voltage is greater than the reference).

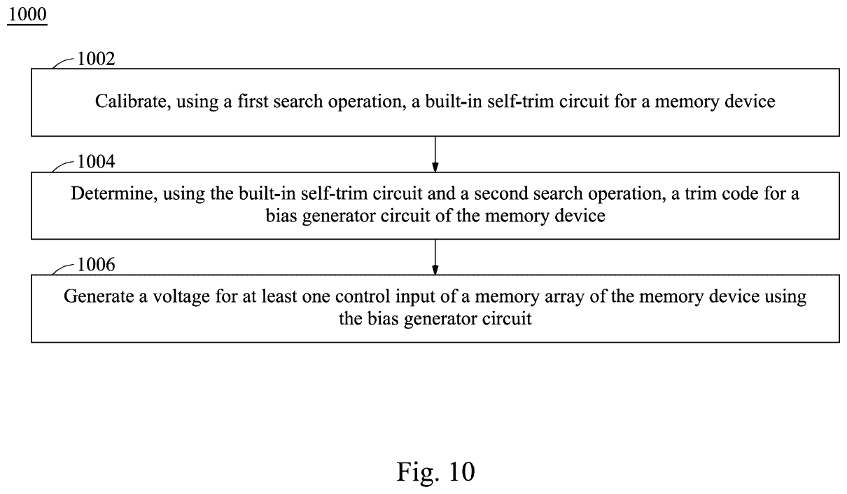

Referring to FIG. 10, illustrated is a flowchart of an example method 800 to operate the disclosed circuits described herein, in accordance with some embodiments of the present disclosure. The method 1000 may be used to perform self-trimming of bias generator circuits according to the techniques described herein. The method 1000 may be performed in connection with any of the systems, devices, circuits, or components described herein. It is understood that additional operations may be provided before, during, and after the method 1000 of FIG. 10, and that some other operations may only be briefly described herein.

In brief overview, the method 1000 starts with operation 1002, including calibrating, using a first search operation (e.g., the search operations described in connection with FIGS. 8 and 9, etc.) a built-in self-trim circuit (e.g., the analog BIST circuit 106, 210, 302, 410, 502, 606, 702, etc.). The method 1000 proceeds with operation 1004, including determining, using the built-in self-trim circuit and a second search operation, a trim value (e.g., trim code) for a bias generator circuit (e.g., bias generator circuit 108, 202, 304, 402, 504, 608, 704, etc.). The method 1000 proceeds with operation 1006, including generating a voltage (e.g., WBL, RBL, WWL, RWL, etc.) for at least one control input of a memory array of the memory device using the bias generator circuit.

Referring to operation 1002, the method 1000 can include calibrating, using a first search operation (e.g., the search operations described in connection with FIGS. 8 and 9, etc.) a built-in self-trim circuit (e.g., the analog BIST circuit 106, 210, 302, 410, 502, 606, 702, etc.). Calibrating the built-in self-trim circuit may be performed using the built-in self-trim circuit by implementing a self-calibration process, as described in connection with FIG. 2. To do so, the built-in self-trim circuit can compare the same voltage using a comparison circuit (e.g., comparison circuit 216, comparison circuit 416, etc.) to determine whether there is an offset. A search operation (e.g., a binary search operation described in connection with FIG. 8, a linear search operation described in connection with FIG. 9) can be implemented using a searching circuit (e.g., the second search circuit 214, the second search circuit 414, etc.) to determine a trim code for the comparison circuit of the built-in self-trim circuit that minimizes the voltage offset between the inputs of the comparison circuit, as described herein.

Referring to operation 1004, the method 1000 can include determining, using the built-in self-trim circuit and a second search operation, a trim value (e.g., trim code) for a bias generator circuit (e.g., bias generator circuit 108, 202, 304, 402, 504, 608, 704, etc.). Once the built-in self-trim circuit has been calibrated, the built-in self-trim circuit can be used to determine trim codes for one or more bias generator circuits. As described herein, the bias generator circuits may include voltage regulators that generate a stable output voltage based on an input reference voltage. Trim codes (e.g., stored in trim register circuits 208, 408, etc.) can be provided to the voltage regulator to tune the output of the voltage regulator. For example, an input voltage offset of a comparison circuit (e.g., operational amplifier, etc.) of the voltage regulator may cause the output voltage of the voltage regulator to deviate from a target value. Trim codes provided to the voltage regulator can be selected to compensate for this offset such that the voltage regulator generates a target output voltage.

To determine the trim codes for the voltage regulator, the built-in self-trim circuit can perform a search operation (e.g., using a first search circuit 212, 412, etc.) as described in connection with FIG. 2. A search operation may be a binary search operation described in connection with FIG. 8, a linear search operation described in connection with FIG. 9, or any other type of search operation. The search operation can iteratively generate candidate trim codes for the voltage regulator, causing the voltage regulator to output a voltage (or a feedback signal) that is received by the built-in self-trim circuit. The built-in self-trim circuit can use the comparison circuit (e.g., the comparison circuit 216, 416) calibrated in step 1002 to compare the output of the bias generator circuit with a voltage reference. The built-in self-trim circuit can automatically update the trim codes as described herein to minimize the comparison, as described herein. This process can be repeated until a stopping condition is reached. In some implementations, the trim code for a bias generator circuit can be stored in persistent memory elements (e.g., OTP circuit 614, OTP circuit 708). In some implementations, the built-in self-trim circuit can iteratively generate trim codes for multiple bias generator circuits, as described herein.

Referring to operation 1006, the method 1000 can include generating a voltage (e.g., WBL, RBL, WWL, RWL, etc.) for at least one control input of a memory array of the memory device using the bias generator circuit. As described in connection with FIG. 1, the bias generator circuits, once calibrated, can be used to generate bias voltages for control inputs of a memory array circuit. To do so, the bias generator circuit(s) can receive one or more corresponding reference voltages. The bias generator circuit can use the reference voltage to generate an output voltage using a voltage regulator, which is tuned according to the trim code generated at step 1004. The output voltage can be provided to at least one control input of a memory device (e.g., memory array circuit 110, 610) to facilitate memory operations.

In one aspect of the present disclosure, a system is disclosed. The system includes a memory circuit, a plurality of bias generator circuits each corresponding to a respective input of the memory circuit, and a built-in self-trim circuit. The built-in self-trim circuit can receive a feedback signal from a first bias generator circuit of the plurality of bias generator circuits. The built-in self-trim circuit can generate a trim code for the first bias generator circuit based on the feedback signal and a voltage reference, causing the first bias generator circuit to generate an output voltage for the respective input of the memory array.

In another aspect of the present disclosure, a built-in self-trim device is disclosed. The built-in self-trim device includes a comparison circuit, a first search circuit coupled to the comparison circuit, a second search circuit configured to generate a trim code for a bias generator circuit based on an output of the comparison circuit, wherein the output is generated based on a feedback signal from the bias generator circuit.

In yet another aspect of the present disclosure, a method is disclosed. The method includes calibrating, using a first search operation, a built-in self-trim circuit for a memory device. the method includes determining, using the built-in self-trim circuit and a second search operation, a trim value for a bias generator circuit of the memory device. The method includes generating a voltage for at least one control input of a memory array of the memory device using the bias generator circuit.

As used herein, the terms “about” and “approximately” generally mean plus or minus 10% of the stated value. For example, about 0.5 would include 0.45 and 0.55, about 10 would include 9 to 11, about 1000 would include 900 to 1100.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A system, comprising:
a memory circuit;
a plurality of bias generator circuits each corresponding to a respective input of the memory circuit; and
a built-in self-trim circuit configured to:
receive a feedback signal from a first bias generator circuit of the plurality of bias generator circuits; and
generate a trim code for the first bias generator circuit based on the feedback signal and a voltage reference, causing the first bias generator circuit to generate an output voltage for the respective input of the memory circuit.

2. The system of claim 1, further comprising a voltage reference generator circuit configured to generate a plurality of voltage references respectively corresponding to the plurality of bias generator circuits.

3. The system of claim 1, wherein the built-in self-trim circuit is further configured to iteratively generate a plurality of trim codes for the first bias generator circuit using a search operation.

4. The system of claim 3, wherein the search operation comprises a binary search operation or a linear search operation.

5. The system of claim 1, further comprising a one-time programmable (OTP) memory circuit, and wherein the built-in self-trim circuit is further configured to provide the trim code for storage in the OTP memory circuit.

6. The system of claim 1, wherein the first bias generator circuit comprises a feedback circuit configured to generate the feedback signal based on the output voltage of the first bias generator circuit.

7. The system of claim 1, wherein the first bias generator circuit comprises a switch configured to provide the output voltage of the first bias generator circuit as the feedback signal.

8. The system of claim 1, wherein the built-in self-trim circuit is further configured perform a self-calibration process prior to generating the trim code.

9. The system of claim 8, wherein the built-in self-trim circuit configured to generate a write signal to store the trim code in a trim register of the first bias generator circuit.

10. The system of claim 1, wherein the built-in self-trim circuit and the memory circuit are defined on the same semiconductor die.

11. A built-in self-trim device, comprising:
a comparison circuit;
a first search circuit coupled to the comparison circuit; and
a second search circuit configured to generate a trim code for a bias generator circuit based on an output of the comparison circuit, wherein the output is generated based on a feedback signal from the bias generator circuit.

12. The built-in self-trim device of claim 11, wherein the first search circuit is configured to generate a second trim code for the comparison circuit during a self-calibration process.

13. The built-in self-trim device of claim 11, further comprising a first switch configured to cause a first input and a second input of the comparison circuit to receive a voltage reference signal during a self-calibration process.

14. The built-in self-trim device of claim 13, further comprising a second switch configured to cause the first input of the comparison circuit to receive the voltage reference signal and the second input of the comparison circuit to receive the feedback signal during a calibration process for the bias generator circuit.

15. The built-in self-trim device of claim 11, wherein the comparison circuit comprises one of a comparator or an operational amplifier.

16. The built-in self-trim device of claim 11, wherein the comparison circuit comprises an input port configured to receive a second trim code corresponding to a voltage offset of the comparison circuit.

17. The built-in self-trim device of claim 11, wherein the second search circuit is further configured to generate a write signal for a trim register of the bias generator circuit.

18. The built-in self-trim device of claim 11, wherein the second search circuit is further configured to generate a plurality of candidate trim codes for the bias generator circuit.

19. A method, comprising:
calibrating, using a first search operation, a built-in self-trim circuit for a memory device;
determining, using the built-in self-trim circuit and a second search operation, a trim code for a bias generator circuit of the memory device; and
generating a voltage for at least one control input of a memory array of the memory device using the bias generator circuit.

20. The method of claim 19, further comprising generating, using the built-in self-trim circuit, a plurality of candidate trim codes for the bias generator circuit based on a feedback signal from the bias generator circuit.
